(19) United States
(12) Patent Application Publication
(10) Pub. No.: US 2025/0344356 A1
(43) Pub. Date: Nov. 6, 2025

(54) Cooling System for a Power Module

(71) Applicant: Infineon Technologies AG, Neubiberg (DE)

(72) Inventors: Benedikt Lackmann, Rüthen-Heddinghausen (DE); Georg Borghoff, Warstein (DE)

(21) Appl. No.: 18/655,859

(22) Filed: May 6, 2024

(51) Int. Cl. H05K 7/20

(52) U.S. Cl. CPC H05K 7/2089

(57) ABSTRACT

A cooling system for a power module includes a cooling plate, an enclosure, and an insert. The enclosure is coupled to the cooling plate such that the enclosure and the cooling plate delimit a chamber that encloses a plurality of protruding bodies of the cooling plate. The insert is vertically aligned with the cooling plate and defines a fluid distribution pathway through the chamber between an inlet and an outlet of the enclosure. The insert includes a baffle that delimits an inflow distribution volume of the fluid distribution pathway from an outflow distribution volume of the fluid distribution pathway, and a plurality of cutouts that direct the fluid distribution pathway from the inflow distribution volume through a cooling volume and into the outflow distribution volume. A profile of the inflow distribution volume changes inversely proportional to a profile of the outflow distribution volume from the inlet to the outlet.

### BACKGROUND

Demand for electronic modules for power applications, commonly referred to as power modules, continues to increase rapidly across a wide range of industries, including automotive, consumer electronics, renewable energy, manufacturing, and medical, among many others. Some power modules for high power density applications, for example inverters based on SiC or Si MOSFETs and/or IGBTs for electric vehicle (EV) applications, may deliver power densities in the 100-200 KW range or higher (e.g., >300 KW). Some such applications utilize complex power modules that may include advanced chipsets, multiple circuits and/or stages, and even smaller standalone power modules integrated into a larger power module. Current solutions for cooling power modules are often insufficient for these more complex, high power density power modules, leading to cooling inhomogeneity across the multiple chips, circuits, stages, integrated power modules, and/or other components. This cooling inhomogeneity may cause temperature variations within the power module that may result in reduced performance and/or reliability issues.

Thus, there is a need for a solution for efficiently cooling complex power modules that is cost-effective and easy to integrate.

### SUMMARY

According to an embodiment of a cooling system for a power module, the cooling system comprises: a cooling plate comprising a plurality of protruding bodies; an enclosure coupled to the cooling plate such that the enclosure and the cooling plate delimit a chamber that encloses the protruding bodies; and an insert vertically aligned with the cooling plate and defining a fluid distribution pathway through the chamber between an inlet and an outlet of the enclosure, the insert comprising: a baffle that delimits an inflow distribution volume of the fluid distribution pathway from an outflow distribution volume of the fluid distribution pathway; and a plurality of cutouts that direct the fluid distribution pathway from the inflow distribution volume through a cooling volume that encloses the protruding bodies and into the outflow distribution volume, wherein a profile of the inflow distribution volume changes inversely proportional to a profile of the outflow distribution volume from the inlet to the outlet.

According to an embodiment of a power electronics assembly, the power electronics assembly comprises: a power module comprising at least two power semiconductor dies enclosed in a housing; and a cooling system mounted to the power module, the cooling system comprising: a cooling plate comprising a plurality of protruding bodies; an enclosure coupled to the cooling plate such that the enclosure and the cooling plate delimit a chamber that encloses the protruding bodies; and an insert vertically aligned with the cooling plate and defining a fluid distribution pathway through the chamber between an inlet and an outlet of the enclosure, the insert comprising: a baffle that delimits an inflow distribution volume of the fluid distribution pathway from an outflow distribution volume of the fluid distribution pathway; and a plurality of cutouts that direct the fluid distribution pathway from the inflow distribution volume through a cooling volume enclosing the protruding bodies and into the outflow distribution volume, wherein a profile of the inflow distribution volume changes inversely proportional to a profile of the outflow distribution volume from the inlet to the outlet.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a partial perspective view of a cooling system for a power module, according to an embodiment.

FIG. 2 illustrates a cross-sectional side view of a cooling system for a power module, according to an embodiment.

FIGS. 3A and 3B illustrate cross-sectional top plan views of a cooling system for a power module, according to embodiments.

FIG. 4 illustrates a cross-sectional side view of a power electronics assembly comprising a cooling system mounted to a plurality of power modules, according to an embodiment.

### DETAILED DESCRIPTION

Described herein is a cooling system for a power module. The cooling system includes an enclosure and a cooling plate that are coupled to one another and delimit a chamber of the cooling system. The enclosure includes an inlet and an outlet that are open to the chamber and enable a cooling fluid to be passed through the chamber. The cooling plate includes a plurality of protruding bodies, e.g., pins or fins, that provide a large surface area for heat extraction from the cooling plate as a cooling fluid passes through the chamber across the protruding bodies.

According to embodiments, the cooling system further includes an insert (e.g., a plastic or metal insert) that is configured to define a fluid distribution pathway through the chamber of the cooling system. More particularly, the insert includes a baffle that separates an inflow distribution volume from an outflow distribution volume, and a base that separates the inflow and outflow distribution volumes from a cooling volume that encloses the protruding bodies of the cooling plate. Cutouts in the base of the insert enable a cooling fluid to pass from the inflow distribution volume through the cooling volume and into the outflow distribution volume, producing a parallel flow of multiple streams of the cooling fluid through the chamber between the inlet and the outlet of the enclosure. The baffle and cutouts of the insert may be structured to separate the incoming cooling fluid from the inlet into these separate streams, to distribute the cooling fluid homogeneously across the protruding bodies of the cooling plate.

Distributing the cooling fluid in the chamber using the insert to produce parallel layers of cooling fluid flow may reduce variation in temperature of the cooling fluid that reaches the cooling plate at different positions along the fluid distribution path between the inlet and outlet. This may ensure that all positions on the cooling plate receive cooling fluid having a similar temperature and may improve cooling uniformity and reduce temperature variation between corresponding positions of a power module to which the cooling system is mounted. Reducing temperature variation within the power module, e.g., temperature variation across multiple chips, circuits, stages, integrated power modules, and/or other components, may improve performance and/or reliability of the power module. Distributing a cooling fluid using the insert described herein may also enable changes to other features of the cooling system that may provide further improvements to cooling efficiency, for example including more protruding bodies that are more closely spaced on the cooling plate.

In contrast to other cooling solutions that may require a redesign of the cooling system or even the power module, with compromises made for size, e.g., footprint, the insert described herein has a low space requirement and may be easily integrated with existing cooling system and power module designs and form factors with few or no modifications needed. For example, a simple spacer between the enclosure and the cooling plate of the cooling system may provide sufficient additional space to accommodate the insert in an existing cooling system design, enabling use of this improved cooling system on existing power module designs. Utilizing a separate parallel layer to distribute the cooling fluid across the cooling plate may enable improved homogeneity of cooling fluid distribution without the need to reduce the footprint of the cooling plate and/or increase the footprint of the cooling system, providing a potential advantage over other solutions for distributing a cooling fluid in a cooling system and compatibility with existing power module designs and form factors. The insert itself may be both inexpensive and simple to manufacture using standard processes such as injection molding in the example of a plastic insert, stamping in the example of a metal insert, a combination of injection molding and stamping in the case of a composite insert, etc. Additionally, this solution offers the flexibility to customize the cooling fluid distribution for different cooling system and power module designs, form factors, footprints, etc. with simple changes to the insert. For example, the shape, size, layout, etc. of the baffle and cutouts of the insert may be easily customized to adjust the quantity and positions of the parallel streams of cooling fluid, fluid velocity, and other attributes of the fluid distribution.

Described next, with reference to the figures, are exemplary embodiments of the cooling system and the corresponding insert.

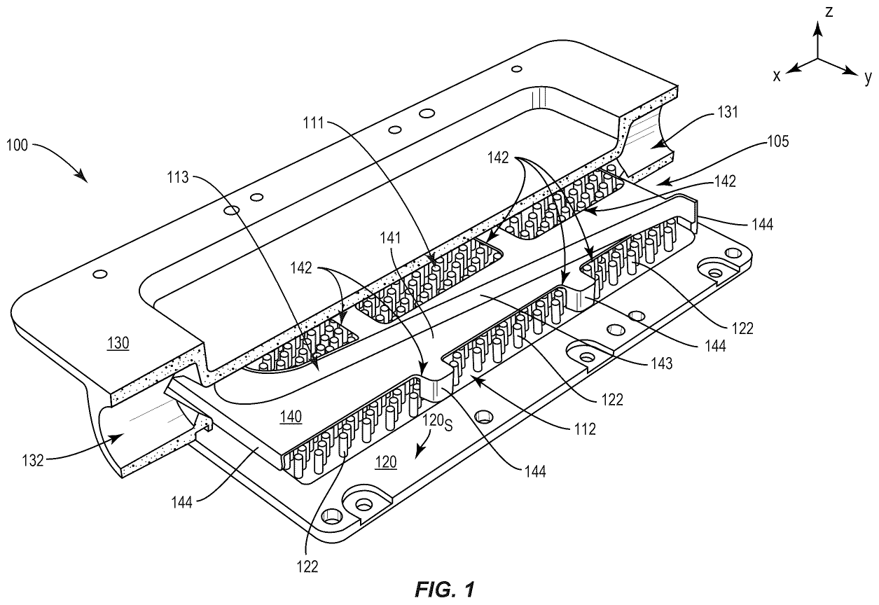

FIG. 1 illustrates a partial perspective view of a cooling system 100 for a power module, according to an embodiment.

The cooling system 100 includes a cooling plate 120 that includes a plurality of protruding bodies 122. The protruding bodies 122 may be pins, fins, etc. that are distributed over and extend from a surface 120_{S} of the cooling plate 120, e.g., in the z direction of FIG. 1. An enclosure 130 is coupled to the cooling plate 120 such that the enclosure 130 and the cooling plate 120 delimit a chamber 105 that encloses the protruding bodies 122. The enclosure includes an inlet 131 and an outlet 132 that are open to the chamber 105 and enable a cooling fluid to pass through the chamber 105. The enclosure 130 and the cooling plate 120 may be directly coupled to each other or may be separated by another feature such as a sealing ring, gasket, etc. that seals the chamber 105. Note that a portion of the enclosure 130 is omitted from FIG. 1 to better illustrate the features enclosed in the chamber 105.

The cooling plate 120 may be formed of a high thermal conductivity metal, e.g., copper, aluminum, an alloy, or another material having a high thermal conductivity. The enclosure 130 may include one or more pieces of metal, plastic, ceramic, composite, and/or another suitable thermally stable material. In some examples, the enclosure 130 is a part of a power module housing (e.g., a part of an inverter housing a cooling circuit). In one embodiment, the enclosure 130 is a molded enclosure formed from a mold compound. A mold compound is a plastic encapsulant typically formed from an organic resin such as an epoxy resin. The plastic encapsulant may include fillers such as non-melting inorganic materials. Catalysts may be used to accelerate the cure reaction of the organic resin. Other materials such as flame retardants, adhesion promoters, ion traps, stress relievers, colorants, etc. may be added to the plastic encapsulant, as appropriate. The mold compound may be formed by injection molding, compression molding, film-assisted molding (FAM), reaction injection molding (RIM), resin transfer molding (RTM), blow molding, etc.

According to an embodiment, the cooling system 100 includes an insert 140 vertically aligned with the cooling plate 120 and enclosed in the chamber 105. The insert 140 may be formed from a plastic, a metal, and/or another suitable material. In one embodiment, the insert 140 consists entirely of a plastic such as a mold compound. As will be described in subsequent figures, the insert 140 defines a fluid distribution pathway through the chamber 105 between the inlet 131 and the outlet 132 of the enclosure 130.

The insert 140 includes a baffle 143 that protrudes from a base 141 of the insert 140 and delimits an inflow distribution volume 111 of the fluid distribution pathway from an outflow distribution volume 113 of the fluid distribution pathway. The inflow distribution volume 111 is open to the inlet 131 and the outflow distribution volume 113 is open to the outlet 132. A plurality of cutouts 142 formed in the base 141 of the insert 140 further define the fluid distribution pathway. In this example, the base 141 of the insert 140 is substantially parallel to the cooling plate 120. The insert 140 includes one or more spacers 144 that separate the base 141 from the cooling plate 120 to form a cooling volume 112 that encloses the protruding bodies 122. In some examples, the spacers 144 may be used to mount the insert 140 to the cooling plate 120. As will be described in further detail, the inflow distribution volume 111, the cooling volume 112, and the outflow distribution volume 113 constitute the fluid distribution pathway that the insert 140 defines.

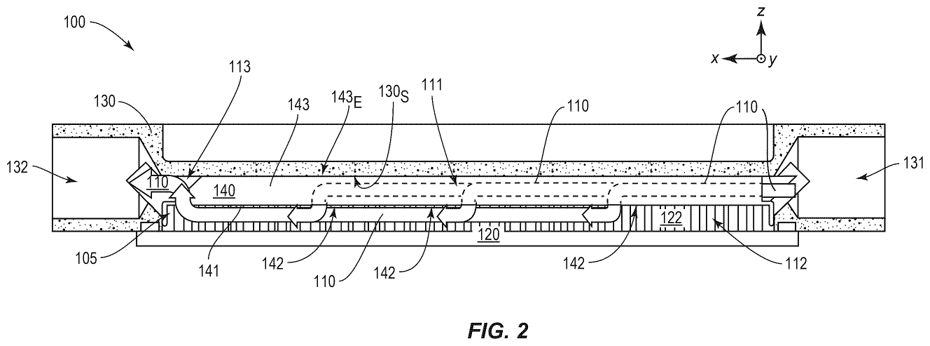

FIG. 2 illustrates a cross-sectional side view of the cooling system 100 for a power module, according to an embodiment. Specifically, FIG. 2 illustrates one example of a fluid distribution pathway 110 through the chamber 105 between the inlet 131 and the outlet 132 of the enclosure 130.

As noted above, the inflow distribution volume 111, the cooling volume 112, and the outflow distribution volume 113 define the fluid distribution pathway 110 between the inlet 131 and the outlet 132 of the enclosure 130. A cooling fluid may be passed through the inlet 131 into the inflow distribution volume 111. The baffle 143 and the plurality of cutouts 142 in the base 141 of the insert 140 direct the cooling fluid along the fluid distribution pathway 110 from the inflow distribution volume 111 through the cooling volume 112 across the protruding bodies 122 and into the outflow distribution volume 113, where the cooling fluid may exit the chamber 105 through the outlet 132. An outer edge 143E of the baffle 143 may form a seal with an interior surface 130_{S} of the enclosure 130 to ensure that the cooling fluid is directed through the cutouts 142 into the cooling volume 112.

FIG. 2 illustrates one example of the baffle 143 and the cutouts 142 of the insert 140 dividing the fluid distribution pathway 110 into multiple streams that enter the cooling volume 112 from the input distribution volume 111 at different positions within the chamber 105, for example at different distances from the inlet 131 along the x direction. The arrows noting the fluid distribution pathway 110 in FIG. 2 and in subsequent figures are included for illustrative purposes only, to indicate a general direction and path. In practice, the actual distribution of a cooling fluid along the fluid distribution pathway 110 may be more widely dispersed, directed along different directions, or may otherwise differ from these illustrative arrows. Other distributions of the cooling fluid are contemplated, for example different positions of the streams of the fluid distribution pathway 110 that are distributed to the cooling volume 112, and may be achieved by changing the shape, size, layout, etc. of the baffle 143 and/or cutouts 142 of the insert 140 as noted previously.

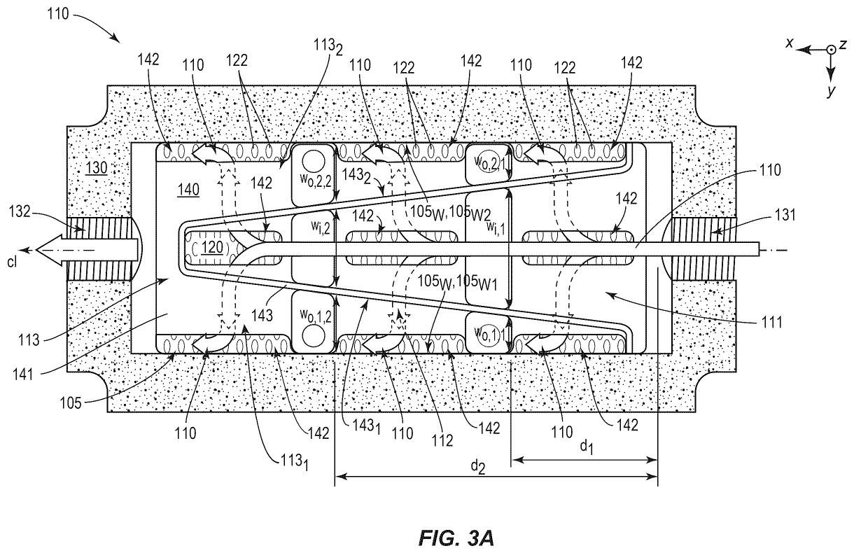

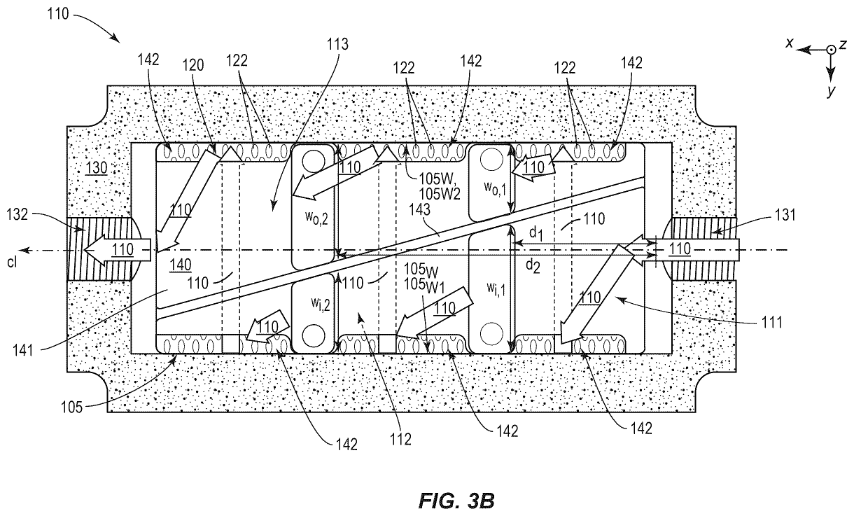

FIGS. 3A and 3B illustrate cross-sectional top plan views of the cooling system 100 for a power module, according to embodiments.

FIG. 3A illustrates one example of the shape of the baffle 143 and the shapes and layout of the cutouts 142 that define the fluid distribution pathway 110. In this embodiment, some of the cutouts 142 are positioned along a centerline cl of the chamber 105 that extends between the inlet 131 and the outlet 132. As illustrated, the cutouts 142 positioned along the centerline cl direct the fluid distribution pathway 110 from the inflow distribution volume 111 into the cooling volume 112 at positions along the centerline cl, although the insert 140 may additionally or alternatively include one or more cutouts 142 positioned along the centerline cl that direct the fluid distribution pathway 110 from the cooling volume 112 into the outflow distribution volume 113.

Some of the cutouts 142 of the insert 140 illustrated in FIG. 3A are arranged along edges of the base 141 and are each delimited by a wall 105_{W} of the chamber 105, for example a first wall 105_{W1} or second wall 105_{W2} opposite the first wall 105_{W1}. Examples in which a cutout 142 is delimited by more than one wall 105_{W} of the chamber 105 are contemplated. As illustrated, the cutouts 142 that are arranged along edges of the base 141 and delimited by the walls 105_{W} (e.g., the walls 105_{W1} and 105_{W2}) direct the fluid distribution pathway 110 from the cooling volume 112 to the outflow distributions volume 113 at positions along walls 105_{W} of the chamber 105, although the insert may additionally or alternatively include one or more cutouts 142 that are delimited by one or more walls 105_{W} of the chamber 105 and direct the fluid distribution pathway 110 from the inflow distribution volume 111 into the cooling volume 112.

Examples in which the insert 140 includes only cutouts 142 that are positioned along the centerline cl or only cutouts 142 that are delimited by one or more walls 105_{W} of the chamber 105 are contemplated. Additionally, cutouts 142 that are positioned elsewhere on the base 141 of the insert are contemplated.

In this embodiment, the baffle 143 has a shape that partly divides the outflow distribution volume 113 into a first portion 113₁ extending along the first wall 105_{W1} of the chamber 105 and a second portion 113₂ extending along the second wall 105_{W2} of the chamber 105. The baffle 143 includes a first segment 143₁ and a second segment 143₂ on opposite sides of the centerline cl of the chamber 105. A distance between the first segment 143₁ and the second segment 143₂ decreases with increasing distance from the inlet 131 along the centerline cl such that a lateral (in the y direction of this example) width wᵢ, and likewise a cross-sectional area, of the inflow distribution volume 111 decreases with increasing distance from the inlet 131 along the centerline cl. In turn, a lateral width wₒ, and likewise a cross-sectional area, of the outflow distribution volume 113 increases proportionally with the decrease in the lateral width wᵢ and cross-sectional area of the inflow distribution volume 111 with increasing distance from the inlet 131 along the centerline cl. In this way, a profile of the inflow distribution volume 111, for example the cross-sectional area of the inflow distribution volume 111, changes inversely proportional to a profile (e.g., the cross-sectional area) of the outflow distribution volume 113 from the inlet 131 to the outlet 132. As an example, FIG. 3A illustrates the inflow distribution volume 111 having a first width w_{i,1} at a first distance d₁ from the inlet 131 and a second width w_{i,2} at a second, greater distance d₂ from the inlet 131 along the centerline cl, with the second width w_{i,2} less than the first width w_{i,1}. The first portion 113₁ and the second portion 113₂ of the outflow distribution volume 113 have first widths w_{o,1,1} and w_{o,2,1}, respectively, at the first distance d₁ and second widths w_{o,1,2} and w_{o,2,2}, respectively, at the second distance d₂ from the inlet 131. That is, the outflow distribution volume 113 has a width of w_{o,1,1}+w_{o,2,1} at the first distance d₁ and a width of w_{o,1,2}+w_{o,2,2} at the second distance d₂ from the inlet 131, with w_{o,1,2}+w_{o,2,2}>w_{o,1,1}+w_{o,2,1}.

FIG. 3B illustrates another example of the shape of the baffle 143 and the shapes and layout of the cutouts 142 that define the fluid distribution pathway 110. In this embodiment, the cutouts 142 of the insert 140 are arranged along edges of the base 141 and are each delimited by a wall 105_{W} of the chamber 105. As illustrated, the cutouts 142 that are delimited by the first wall 105_{W1} direct the fluid distribution pathway 110 from the input distribution volume 111 into the cooling volume 112, and the cutouts 142 that are delimited by the second wall 105_{W2} direct the fluid distribution pathway 110 from the cooling volume 112 to the outflow distributions volume 113. Other arrangements of the cutouts 142 along the first wall 105_{W1}, the second wall 105_{W2}, and/or other walls 105_{W} of the chamber 105 are contemplated.

In this embodiment, the baffle 143 extends diagonally through the chamber 105 between the inflow distribution volume 111 and the outflow distribution volume 113. The baffle 143 is oriented such that a distance between the baffle 143 and the first wall 105_{W1} of the chamber 105 decreases with increasing distance from the inlet 131 along the centerline cl and a distance between the baffle 143 and the second wall 105_{W2} increases with increasing distance from the inlet 131 along the centerline cl. In this way, a profile (e.g., the width, the cross-sectional area) of the inflow distribution volume 111 changes inversely proportional to a profile (e.g., the width, the cross-sectional area) of the outflow distribution volume 113 from the inlet 131 to the outlet 132. As an example, FIG. 3B illustrates the inflow distribution volume 111 having a first width w_{i,1} and the outflow distribution volume 113 having a first width w_{o,1} at a first distance d₁ along the centerline cl. The inflow distribution volume 111 has a second width w_{i,2} and the outflow distribution volume 113 has a second width w_{o,2} at a second, greater distance d₂ along the centerline cl. The respective profiles of the inflow distribution volume 111 and the outflow distribution volume 113 change with increasing distance from the inlet 131 along the centerline cl such that the second width w_{i,2} of the inflow distribution volume 111 is less than the first width w_{i,1} of the inflow distribution volume 111 and the second width w_{o,2} of the outflow distribution volume 113 is greater than the first width w_{o,1} of the outflow distribution volume 113.

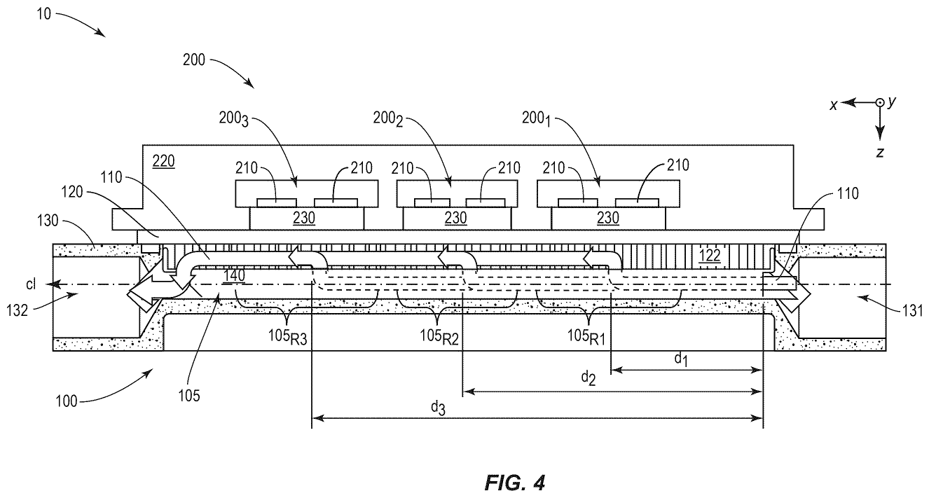

FIG. 4 illustrates a cross-sectional side view of a power electronics assembly 10 comprising the cooling system 100 mounted to a plurality of power modules 200, according to an embodiment.

The plurality of power modules 200 of this example includes a first power module 200₁, a second power module 200₂, and a third power module 200₃, although other examples may include fewer power modules 200 (e.g., a single power module 200 that includes a plurality of circuits, e.g., half-bridges) or may further include additional power modules 200 that are not illustrated. Each power module 200 of this example includes at least two power semiconductor dies 210. In this example, each power semiconductor die 210 of the first power module 200₁, the second power module 200₂, and the third power module 200₃ is attached to a substrate 230. The power semiconductor dies 210 of the first power module 200₁, the second power module 200₂, and the third power module 200₃ are enclosed in a housing 220. While the first power module 200₁, the second power module 200₂, and the third power module 200₃ of FIG. 4 share a common housing 220, examples in which the power semiconductor dies 210 of the first power module 200₁, the second power module 200₂, and the third power module 200₃ are enclosed in separate housings 220 are contemplated.

Each power semiconductor die 210 may include one or more devices, e.g., one or more transistors, diodes, resistors, capacitors, and/or other types of active or passive devices. One or more of the power semiconductor dies 210 included in the first power module 200₁, the second power module 200₂, the third power module 200₃, and/or other power modules 200 may be a vertical power semiconductor die (e.g., a vertical power transistor die). For a vertical power transistor die, the primary current flow path is between the front and back sides of the power semiconductor die 210 (along the z direction in FIG. 4). In one embodiment, one or more power semiconductor dies 210 are SiC transistor dies such as SiC power MOSFET (metal-oxide-semiconductor field-effect transistor) dies. One or more of the power semiconductor dies 210 included in the power modules 200 may be a Si power MOSFET die, HEMT (high-electron mobility transistor) die, IGBT (insulated-gate bipolar transistor) die, JFET (junction field-effect transistor) die, etc. The power semiconductor dies 210 may all be of a similar or identical design (e.g., device type, structure, materials, dimensions, etc.), or some or each of the power semiconductor dies 210 may have different designs. Various arrangements of designs of power semiconductor dies 210 of the power modules 200 are contemplated. One or more of the power modules 200 and/or one or more of the power semiconductor dies 210 included in each power module 200 may be arranged to form all or part of a circuit, such as a DC/AC inverter, a DC/DC converter, an AC/DC converter, a DC/AC converter, an AC/AC converter, a multi-phase inverter, a half-bridge, motor driver, etc. For example, the power semiconductor dies 210 of each of the first power module 200₁, the second power module 200₂, and the third power module 200₃ may form a DC/AC inverter, a DC/DC converter, an AC/DC converter, a DC/AC converter, an AC/AC converter, a multi-phase inverter, a half-bridge, motor driver, etc. In one example, the semiconductor dies 210 of each of the first power module 200₁, the second power module 200₂, and the third power module 200₃ form a half-bridge. In some examples, some or all of the power semiconductor dies 210 of a power module 200, for example a circuit of a power module 200, are electrically coupled to one or more other power modules 200.

The housing 220 may be a frame housing, for example a molded frame housing that includes a mold compound. The housing 220 may include one or more pieces of metal, plastic, composite, and/or other suitable material that is structured and arranged to enclose the power semiconductor dies 210. The housing 220 may be a single piece or may include a base, a lid, walls, and/or other pieces. The housing 220 may include openings that provide access to the power semiconductor dies 210 and/or the substrates 230, for example to contact pads and/or traces of the substrates 230. Alternatively, or additionally, the housing 220 may include feedthrough contacts such as pins or terminals that provide electrical contact to the power semiconductor dies 210.

Examples of the substrates 230 include DCB (direct copper bonded) or AMB (active metal brazed) substrates, printed circuit boards (PCB), lead frames, or other substrates, e.g., insulated metal substrates (IMS), etc. A substrate 230 may include a metallization layer that includes metallic (e.g., copper, aluminum, an alloy) pads, traces, and/or islands that may each be electrically coupled to one or more of the power semiconductor dies 210 (e.g., directly coupled, electrically coupled by a bond wire, metallic ribbon, or other electrically conductive body). The substrates 230 of the power modules 200 may all be of the same type, or one or more of the substrates 230 may be of a different type than another substrate 230.

According to an embodiment, the cooling system 100 is mounted to the plurality of power modules 200, including the first power module 200₁, the second power module 200₂, and the third power module 200₃. In some examples, the cooling system 100 (e.g., the cooling plate 120) is sintered or soldered to the power modules 200. Alternatively, the cooling system 100 may be mounted to the power modules 200 using screws, clips (e.g., clips formed as part of the housing 220), tape, glue, etc. In this example, the cooling plate 120 is adjacent to each of the substrates 230 to which the power semiconductor dies 210 are attached. A thermal interface material (TIM) may be applied between the cooling plate 120 and one or more of the substrates 230 to improve heat extraction from the power modules 200 into the cooling system 100.

In the power electronics assembly 10 illustrated in FIG. 4, the first power module 200₁ is vertically aligned with a first region 105_{R1} of the chamber 105 of the cooling system 100, the second power module 200₂ is vertically aligned with a second region 105_{R2} of the chamber 105 of the cooling system 100, and the third power module 200₃ is vertically aligned with a third region 105_{R3} of the chamber 105 of the cooling system 100. The first region 105_{R1} of the chamber 105 is closer to the inlet 131 than the second region 105_{R2} of the chamber 105 along the centerline cl of the chamber 105. The second region 105_{R2} of the chamber 105 is closer to the inlet 131 than the third region 105_{R3} of the chamber 105 along the centerline cl of the chamber 105. As described with reference to the previous figures, the insert 140 of the cooling system 100 is configured to homogenize a temperature of a cooling fluid that passes along the fluid distribution pathway 110 through the first region 150_{R1}, the second region 150_{R2}, and the third region 150_{R3} of the chamber 105 during operation of the first power module 200₁, the second power module 200₂, and the third power module 200₃. In the example of the power electronics assembly 10, including the insert 140 in the cooling system 100 as described herein may reduce variation in temperature of the cooling fluid reaching the cooling plate 120 a different positions along the fluid distribution path 110 and may ensure that all portions of the cooling plate 120, for example those portions in regions 105_{R1}, 105_{R2}, and 105_{R3}, receive cooling fluid having a similar temperature. This may improve cooling uniformity and reduce temperature variation between power modules 200, for example between the first power module 200₁, the second power module 200₂, and the third power module 200₃, which may improve performance and/or reliability of the power modules 200.

Although the present disclosure is not so limited, the following numbered examples demonstrate one or more aspects of the disclosure.

Example 1. A cooling system for a power module, the cooling system comprising: a cooling plate comprising a plurality of protruding bodies; an enclosure coupled to the cooling plate such that the enclosure and the cooling plate delimit a chamber that encloses the protruding bodies; and an insert vertically aligned with the cooling plate and defining a fluid distribution pathway through the chamber between an inlet and an outlet of the enclosure, the insert comprising: a baffle that delimits an inflow distribution volume of the fluid distribution pathway from an outflow distribution volume of the fluid distribution pathway; and a plurality of cutouts that direct the fluid distribution pathway from the inflow distribution volume through a cooling volume that encloses the protruding bodies and into the outflow distribution volume, wherein a profile of the inflow distribution volume changes inversely proportional to a profile of the outflow distribution volume from the inlet to the outlet.

Example 2. The cooling system of example 1, wherein the inflow distribution volume is open to the inlet, and wherein the outflow distribution volume is open to the outlet.

Example 3. The cooling system of example 1 or 2, wherein the plurality of cutouts are formed in a base of the insert, and wherein the baffle protrudes from the base of the insert.

Example 4. The cooling system of example 3, wherein the base of the insert is substantially parallel to the cooling plate.

Example 5. The cooling system of example 3, wherein the insert comprises a plurality of spacers that separate the base from the cooling plate to form the cooling volume.

Example 6. The cooling system of any of examples 1 through 5, wherein an outer edge of the baffle forms a seal with an interior surface of the enclosure.

Example 7. The cooling system of any of examples 1 through 6, wherein the insert comprises a plastic.

Example 8. The cooling system of any of examples 1 through 7, wherein a lateral width of the inflow distribution volume decreases with increasing distance from the inlet along a centerline of the chamber that extends between the inlet and the outlet.

Example 9. The cooling system of example 8, wherein a lateral width of the outflow distribution volume increases proportionally with the decrease in the lateral width of the inflow distribution volume with increasing distance from the inlet along the centerline.

Example 10. The cooling system of any of examples 1 through 9, wherein a cross-sectional area of the inflow distribution volume decreases with increasing distance from the inlet along a centerline of the chamber that extends between the inlet and the outlet.

Example 11. The cooling system of example 10, wherein a cross-sectional area of the outflow distribution volume increases proportionally with the decrease in the cross-sectional area of the inflow distribution volume with increasing distance from the inlet along the centerline.

Example 12. The cooling system of any of examples 1 through 11, wherein at least one of the plurality of cutouts of the insert is delimited by a wall of the chamber.

Example 13. The cooling system of any of examples 1 through 12, wherein at least one of the plurality of cutouts of the insert is positioned along a centerline of the chamber that extends between the inlet and the outlet.

Example 14. The cooling system of any of examples 1 through 13, wherein the baffle has a shape that partly divides the outflow distribution volume into a first portion extending along a first wall of the chamber and a second portion extending along a second wall of the chamber opposite the first wall.

Example 15. The cooling system of any of examples 1 through 14, wherein the baffle comprises a first segment and a second segment on opposite sides of a centerline of the chamber that extends between the inlet and the outlet, and wherein a distance between the first segment and the second segment decreases with increasing distance from the inlet along the centerline.

Example 16. The cooling system of any of examples 1 through 13, wherein the baffle extends diagonally through the chamber between the inflow distribution volume and the outflow distribution volume.

Example 17. The cooling system of any of examples 1 through 13 or 16, wherein a distance between the baffle and a wall of the chamber decreases with increasing distance from the inlet along a centerline of the chamber that extends between the inlet and the outlet.

Example 18. A power electronics assembly, comprising: a power module comprising at least two power semiconductor dies enclosed in a housing; and a cooling system mounted to the power module, the cooling system comprising: a cooling plate comprising a plurality of protruding bodies; an enclosure coupled to the cooling plate such that the enclosure and the cooling plate delimit a chamber that encloses the protruding bodies; and an insert vertically aligned with the cooling plate and defining a fluid distribution pathway through the chamber between an inlet and an outlet of the enclosure, the insert comprising: a baffle that delimits an inflow distribution volume of the fluid distribution pathway from an outflow distribution volume of the fluid distribution pathway; and a plurality of cutouts that direct the fluid distribution pathway from the inflow distribution volume through a cooling volume enclosing the protruding bodies and into the outflow distribution volume, wherein a profile of the inflow distribution volume changes inversely proportional to a profile of the outflow distribution volume from the inlet to the outlet.

Example 19. The power electronics assembly of example 18, wherein the power module is a first power module, wherein the power electronics assembly further comprises one or more additional power modules to which the cooling system is mounted, each of the one or more additional power modules comprising at least two power semiconductor dies, wherein the first power module is vertically aligned with a first region of the chamber of the cooling system, wherein a second power module is vertically aligned with a second region of the chamber of the cooling system, and wherein the first region of the chamber is closer to the inlet than the second region of the chamber along a centerline of the chamber that extends between the inlet and the outlet.

Example 20. The power electronics assembly of example 19, wherein the insert of the cooling system is configured to homogenize a temperature of a cooling fluid that passes through the first region and the second region of the chamber of the cooling system during operation of the first power module and the second power module.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to include all possible conjunctive and disjunctive combinations, unless expressly noted otherwise. For example, the expression “A and/or B” should be interpreted to mean only A, only B, or both A and B. The expression “at least one of” should be interpreted in the same manner as “and/or”, unless expressly noted otherwise. For example, the expression “at least one of A and B” should be interpreted to mean only A, only B, or both A and B.

It is to be understood that the features of the various embodiments described herein can be combined with each other, unless specifically noted otherwise.

Although specific embodiments have been illustrated and described herein, it will be appreciated by those of ordinary skill in the art that a variety of alternate and/or equivalent implementations can be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A cooling system for a power module, the cooling system comprising:
a cooling plate comprising a plurality of protruding bodies;
an enclosure coupled to the cooling plate such that the enclosure and the cooling plate delimit a chamber that encloses the protruding bodies; and
an insert vertically aligned with the cooling plate and defining a fluid distribution pathway through the chamber between an inlet and an outlet of the enclosure, the insert comprising:
a baffle that delimits an inflow distribution volume of the fluid distribution pathway from an outflow distribution volume of the fluid distribution pathway; and
a plurality of cutouts that direct the fluid distribution pathway from the inflow distribution volume through a cooling volume that encloses the protruding bodies and into the outflow distribution volume,
wherein a profile of the inflow distribution volume changes inversely proportional to a profile of the outflow distribution volume from the inlet to the outlet.

2. The cooling system of claim 1,
wherein the inflow distribution volume is open to the inlet, and
wherein the outflow distribution volume is open to the outlet.

3. The cooling system of claim 1,
wherein the plurality of cutouts are formed in a base of the insert, and
wherein the baffle protrudes from the base of the insert.

4. The cooling system of claim 3, wherein the base of the insert is substantially parallel to the cooling plate.

5. The cooling system of claim 3, wherein the insert comprises a plurality of spacers that separate the base from the cooling plate to form the cooling volume.

6. The cooling system of claim 1, wherein an outer edge of the baffle forms a seal with an interior surface of the enclosure.

7. The cooling system of claim 1, wherein the insert comprises a plastic.

8. The cooling system of claim 1, wherein a lateral width of the inflow distribution volume decreases with increasing distance from the inlet along a centerline of the chamber that extends between the inlet and the outlet.

9. The cooling system of claim 8, wherein a lateral width of the outflow distribution volume increases proportionally with the decrease in the lateral width of the inflow distribution volume with increasing distance from the inlet along the centerline.

10. The cooling system of claim 1, wherein a cross-sectional area of the inflow distribution volume decreases with increasing distance from the inlet along a centerline of the chamber that extends between the inlet and the outlet.

11. The cooling system of claim 10, wherein a cross-sectional area of the outflow distribution volume increases proportionally with the decrease in the cross-sectional area of the inflow distribution volume with increasing distance from the inlet along the centerline.

12. The cooling system of claim 1, wherein at least one of the plurality of cutouts of the insert is delimited by a wall of the chamber.

13. The cooling system of claim 1, wherein at least one of the plurality of cutouts of the insert is positioned along a centerline of the chamber that extends between the inlet and the outlet.

14. The cooling system of claim 1, wherein the baffle has a shape that partly divides the outflow distribution volume into a first portion extending along a first wall of the chamber and a second portion extending along a second wall of the chamber opposite the first wall.

15. The cooling system of claim 1,
wherein the baffle comprises a first segment and a second segment on opposite sides of a centerline of the chamber that extends between the inlet and the outlet, and
wherein a distance between the first segment and the second segment decreases with increasing distance from the inlet along the centerline.

16. The cooling system of claim 1, wherein the baffle extends diagonally through the chamber between the inflow distribution volume and the outflow distribution volume.

17. The cooling system of claim 1, wherein a distance between the baffle and a wall of the chamber decreases with increasing distance from the inlet along a centerline of the chamber that extends between the inlet and the outlet.

18. A power electronics assembly, comprising:
a power module comprising at least two power semiconductor dies enclosed in a housing; and
a cooling system mounted to the power module, the cooling system comprising:
a cooling plate comprising a plurality of protruding bodies;
an enclosure coupled to the cooling plate such that the enclosure and the cooling plate delimit a chamber that encloses the protruding bodies; and
an insert vertically aligned with the cooling plate and defining a fluid distribution pathway through the chamber between an inlet and an outlet of the enclosure, the insert comprising:
a baffle that delimits an inflow distribution volume of the fluid distribution pathway from an outflow distribution volume of the fluid distribution pathway; and
a plurality of cutouts that direct the fluid distribution pathway from the inflow distribution volume through a cooling volume enclosing the protruding bodies and into the outflow distribution volume,
wherein a profile of the inflow distribution volume changes inversely proportional to a profile of the outflow distribution volume from the inlet to the outlet.

19. The power electronics assembly of claim 18,
wherein the power module is a first power module,
wherein the power electronics assembly further comprises one or more additional power modules to which the cooling system is mounted, each of the one or more additional power modules comprising at least two power semiconductor dies,
wherein the first power module is vertically aligned with a first region of the chamber of the cooling system,
wherein a second power module is vertically aligned with a second region of the chamber of the cooling system, and
wherein the first region of the chamber is closer to the inlet than the second region of the chamber along a centerline of the chamber that extends between the inlet and the outlet.

20. The power electronics assembly of claim 19, wherein the insert of the cooling system is configured to homogenize a temperature of a cooling fluid that passes through the first region and the second region of the chamber of the cooling system during operation of the first power module and the second power module.
